(19) United States
(12) Patent Application Publication
(10) Pub. No.: US 2026/0198317 A1
(43) Pub. Date: Jul. 9, 2026

(54) ELECTRICAL POWER CONVERTER FOR AN INDUSTRIAL PROCESS ASSEMBLY, PREFERABLY PLASMA PROCESS ASSEMBLY OR HEATING ASSEMBLY

(71) Applicant: TRUMPF HÜTTINGER GMBH + CO. KG, Freiburg (DE)

(72) Inventors: Guido Dieter HODAPP, Emmendingen (DE); Simon ZEHNLE, Schuttertal (DE)

(21) Appl. No.: 19/550,312

(22) Filed: Feb. 26, 2026

Related U.S. Application Data
(63) Continuation of application No. PCT/EP2024/074319, filed on Aug. 30, 2024.

(30) Foreign Application Priority Data
Sep. 1, 2023 (DE) 10 2023 123 666.0

(51) Int. Cl. H10W 40/47; H05K 7/20; H10W 40/00; H10W 40/20; H10W 40/22; H10W 40/60; H10W 90/10

(52) U.S. Cl. CPC H10W 40/47; H05K 7/20927; H10W 40/037; H10W 40/228; H10W 40/235; H10W 90/10; H10W 40/611

(57) ABSTRACT

An electrical power converter for an industrial process assembly, including a heat sink, an electrical unit to be cooled, a circuit board, and further electronic components. The unit to be cooled is integrally bonded to the heat sink, which dissipates heat from the electrical unit and includes a cooling channel and both a coolant inlet and outlet, which are fluidically connected to the cooling channel. The coolant inlet and outlet are configured to supply and discharge cooling liquid. The heat sink is monolithic, mechanically and thermally connected to the electrical unit, and detachably fastened to a cooling unit with a first fluid port. A first fluidic connection is formed between the coolant inlet and the first fluid port when the heat sink is fastened to the cooling unit. The heat sink is fastened to the cooling unit simultaneously with the first fluidic connection being fluid-tightly sealed.

### CROSS REFERENCE TO RELATED APPLICATIONS

This application is a continuation of International Application No. PCT/EP2024/074319 (WO 2025/046088A1 ), filed on Aug. 30, 2024, and claims benefit to German Patent Application No. DE 10 2023 123 666.0, filed on Sep. 1, 2023. The aforementioned applications are hereby incorporated by reference herein.

### FIELD

The invention relates to an electrical power converter for an industrial process assembly, and to a method for assembling such an electrical power converter.

### BACKGROUND

The development lies in the field of electrical power conversion for special power-intensive and instability-prone industrial processes, such as plasma excitation, plasma coating processes, gas laser excitation, particle accelerators, charging and discharging systems for large batteries, such as flow batteries, melting of solids, heating and/or gasification of liquids by, for example, microwave energy or induction heating. All these processes have in common that they are designed to generate and accelerate charged atomic particles in a gas and/or plasma environment or liquid. All these processes also have in common that they have a high power consumption, which is in the range of 1 kW or more, in particular 10 kW or more, preferably 100 kW or more. Many of these processes also have a very high requirement for the stability of the power supply because the processes are highly complex, such as semiconductor manufacturing using plasma processes and/or heating by electromagnetic fields. Typically, power is converted from a mains frequency, which is in the range of approximately 50 Hz to 60 Hz, to different frequencies, which can range from 1 kHz to 200 MHz. Conversion to direct current power, also referred to as DC power, is also conceivable. Converting electrical power to other frequencies requires a plurality of electronic components and modules, in particular power semiconductor components such as transistors or diodes designed for currents ≥10 A and voltages ≥400 V. These electronic components and modules generate waste heat during operation. The waste heat often arises over a very limited area of just a few mm². It presents a particular challenge to dissipate this waste heat in order to protect the components and/or modules from destruction due to overheating. Often, very large and material-intensive heat sinks are provided for this purpose, the production of which is very expensive.

In the prior art, the heat energy is dissipated by cooling using a cooling plate. When cooling with such a conventional cooling plate, the heat transfer from the electrical component, which may have a copper layer, to the cooling medium is achieved by applying a material, such as thermal paste, to the thermal interface, thereby dissipating the generated heat. Such heat interface material proves to be disadvantageous. Firstly, it represents another heat transfer with thermal resistance, and secondly, it is subject to wear, which gradually deteriorates its effectiveness during operation. The area of the cooling plate is also increased or the number and performance of the components are reduced in order to dissipate a larger amount of heat or generate a small amount of heat. Both options prove to be insufficient. Since the installation space in the housing of such a power supply is limited, an expansion of the cooling area is not possible indefinitely. Reducing the performance of individual components is also not expedient. Overall, the inadequate cooling of the electrical components results in costs.

In many technical applications, in particular in the field of power electronics, there is a need to detach a unit to be cooled, such as a semiconductor element or semiconductor assembly, from the rest of the module when necessary. To enable the unit to be cooled to be detachably attached to the heat sink, the units to be cooled are often detachably attached to the associated heat sinks, for example using thermal paste. This results in the disadvantage of a comparatively low thermal coupling between the unit to be cooled and the heat sink.

### SUMMARY

In an embodiment, the present disclosure provides an electrical power converter for an industrial process assembly, comprising a heat sink, an electrical unit to be cooled, a circuit board, and further electronic components. The further electronic components and the electrical unit to be cooled are arranged on or against the circuit board and are connected to electrical contacts. The unit to be cooled has an integrally bonded connection to the heat sink. The heat sink is configured to dissipate heat from the electrical unit to be cooled. The heat sink includes a cooling channel and both a coolant inlet and a coolant outlet, which are both fluidically connected to the cooling channel, the coolant inlet and the coolant outlet being configured to supply and discharge cooling liquid. The heat sink is constructed in monolithic form from one material. The heat sink is mechanically and thermally connected to the electrical unit to be cooled. The heat sink is detachably fastened to a cooling unit comprising a first fluid port. A first fluidic connection is configured to be formed between the coolant inlet of the heat sink and the first fluid port of the cooling unit when the heat sink is fastened to the cooling unit. The heat sink is configured to be fastened to the cooling unit simultaneously with the first fluidic connection being fluid-tightly sealed.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows an electrical power converter in an industrial process assembly, preferably a plasma process assembly or a heating assembly;

FIG. 2 shows a longitudinal section through a unit to be cooled, a heat sink and a cooling unit that supplies the heat sink with coolant;

FIG. 3 shows a circuit board with two units to be cooled which are arranged on a circuit board, the circuit board being detachably attachable to a cooling unit;

FIG. 4a shows a sectional view of the circuit board with the units to be cooled arranged on it together with a carrier unit;

FIG. 4b shows a view of the entire carrier unit with the circuit board arranged on it;

FIG. 5 shows a further view of the carrier unit in longitudinal section;

FIG. 6 shows a sectional view of the carrier unit obliquely from the underside, in which a cooling insert and pipes for the fluid supply of the cooling insert can be seen; and

FIG. 7 shows a sectional view of the entire carrier unit obliquely from the underside, in which the cooling insert, the pipes and the coolant connections can be seen.

### DETAILED DESCRIPTION

In an embodiment, the present disclosure provides an electrical power converter that enables improved thermal coupling between the heat sink and a unit to be cooled and improves ease of maintenance.

The foregoing is achieved by an electrical power converter according to the present disclosure. Disclosed is therefore an electrical power converter for an industrial process assembly, preferably a plasma process assembly or a heating assembly. The electrical power converter has:
a heat sink,
a unit to be cooled, in particular an electrical unit, preferably a semiconductor assembly, preferably having a power semiconductor component,
a circuit board,
further electronic components, wherein these further electronic components and the unit to be cooled are arranged on or against the circuit board and are connected to electrical contacts,
wherein the unit to be cooled has a fixed, in particular integrally bonded, connection to the heat sink, and
wherein the heat sink is configured to dissipate heat from the unit to be cooled, in particular an electrical unit, preferably a semiconductor assembly. The heat sink comprises a cooling channel and, in particular, a first cooling wall, arranged on the side of the cooling channel facing the unit to be cooled. Furthermore, the heat sink comprises a coolant inlet and a coolant outlet, which are both fluidically connected to the cooling channel, for the supply and discharge of coolant, in particular cooling liquid, preferably cooling water. The heat sink is constructed in monolithic form from one material. The heat sink is mechanically and thermally connected to the unit to be cooled. Furthermore, the heat sink is detachably fastened to a cooling unit comprising a first fluid port and in particular, additionally, a second fluid port. When the heat sink is fastened to the cooling unit, a first fluidic connection is formed between the coolant inlet of the heat sink and the first fluid port of the cooling unit, and in particular, additionally, a second fluidic connection is formed between the coolant outlet of the heat sink and the second fluid port of the cooling unit. The heat sink is preferably further designed in such a way that, when the heat sink is fastened to the cooling unit, the first fluidic connection and in particular also the second fluidic connection are fluid-tightly sealed simultaneously.

In an aspect, the electrical power converter also has:
a further heat sink,
a further unit to be cooled, in particular an electrical unit, preferably a semiconductor assembly, preferably having a power semiconductor component,
wherein the further unit to be cooled has a fixed, in particular integrally bonded, connection to the further heat sink, and
the further heat sink is configured to dissipate heat from the further unit to be cooled.

In an aspect, the electrical power converter also has:
a plurality of heat sinks,
a plurality of units to be cooled, in particular electrical units, preferably semiconductor assemblies, each preferably having one or more power semiconductor component(s),
wherein the units to be cooled each have a fixed, in particular integrally bonded, connection to one of the heat sinks, and
the heat sinks are configured to dissipate heat from the units to be cooled that are connected to them.

The heat sinks have the following in all aspects mentioned above and below:
a cooling channel,
a coolant inlet and a coolant outlet, which are both fluidically connected to the cooling channel, for the supply and discharge of coolant, in particular cooling liquid, preferably cooling water,
wherein
   the heat sinks are each constructed in monolithic form from one material,
   the heat sinks are each mechanically and thermally connected to the unit to be cooled that is connected to them,
   the heat sinks are each detachably fastened to a cooling unit comprising a plurality of fluid ports,
   when the heat sinks are fastened to the cooling unit, a fluidic connection is formed between the coolant inlet of the heat sink and the associated fluid port of the cooling unit, and
   when the heat sinks are fastened to the cooling unit, the fluidic connections are simultaneously fluid-tightly sealed.

The properties disclosed below for “the heat sink” and “the unit to be cooled” and their connections and interaction with further units or devices also apply analogously to all of the further and plurality of heat sinks and units to be cooled which are disclosed herein.

Monolithic means that the heat sink is made from one material that forms an atomic bond at all connection points. This can be achieved through various methods. One manufacturing process can be an additive manufacturing process, e.g., using laser melting. In another method, the heat sink can be produced by pressing a plurality of layers together under very high pressure. In yet another method, the heat sink can be produced entirely by pressing it into a mold. Such an assembly allows very high power to be dissipated in a very small space. This allows dimensions, in particular for conductor tracks, to be kept very short. The assembly is also particularly easy to maintain.

The heat sink allows for detachable fastening of the heat sink in a cooling unit. The cooling unit is designed to supply coolant to the heat sink and to discharge coolant. The heat sink can, for example, be designed in such a way that fluid-tight fluidic connections can be formed between the heat sink and the cooling unit when the heat sink is fastened in the cooling unit. The heat sink can be removed, together with the unit to be cooled which is attached to the heat sink, from the cooling unit if necessary. This is particularly advantageous in terms of maintenance and repair. According to the described embodiments, the unit to be cooled can, for example, be removed from the cooling unit together with the heat sink.

This development allows, for example, the unit which is to be cooled to be mechanically, fixedly connected to the heat sink. The result of the development is preferably to realize the connection between the unit to be cooled and the heat sink with as little additional material and to be as thin as possible. In view of the considerations, simulations and experiments for this development, the foregoing is particularly achieved when the heat sink through which fluid flows is fixedly connected, in particular in an integrally bonded manner, to the unit to be cooled. This can be done, for example, by a soldered connection, sintering, pressing or direct copper bonding (DCB). The term ‘fixedly’ here can mean: ‘only destructively detachable’. This means using means of connection that cannot be detached even with tools without destroying either the unit 10 to be cooled or the heat sink 5 or both components. In this case too, the unit to be cooled can be removed together with the heat sink from the cooling unit, for example for maintenance purposes. By mechanically, fixedly attaching the unit to be cooled to the heat sink, improved thermal coupling between the unit to be cooled and the heat sink as well as better heat transfer from the unit to be cooled to the heat sink can be achieved.

Furthermore, the electrical power converter can have an electronics module comprising a heat sink as described above and a unit to be cooled that is mechanically, fixedly connected to the heat sink.

The electronics module, which comprises the heat sink and the unit to be cooled that is mechanically, fixedly connected to the heat sink, can, for example, be inserted into the cooling unit and removed again from the cooling unit in its entirety. This allows access to the unit to be cooled.

The electrical power converter can further have: a cooling unit for supplying a heat sink, which has a coolant inlet and a coolant outlet, with coolant, in particular cooling liquid, preferably cooling water. The cooling unit can have a first flow channel and a second flow channel. Furthermore, the cooling unit can have a first fluid port that is fluidically connected to the first flow channel and in particular a second fluid port that is fluidically connected to the second flow channel. The cooling unit can be designed in such a way that the heat sink can be detachably fastened to the cooling unit and that, when the heat sink is fastened to the cooling unit, a first fluidic connection can be formed between the coolant inlet of the heat sink and the first fluid port of the cooling unit, as well as a second fluidic connection between the coolant outlet of the heat sink and the second fluid port of the cooling unit. Furthermore, the heat sink can be designed in particular in such a way that, when the heat sink is fastened to the cooling unit, the first fluidic connection and the second fluidic connection are simultaneously fluid-tightly sealed.

The cooling unit can be designed, for example, to supply a single heat sink with coolant, but it can also be designed, for example, to supply a plurality of heat sinks with coolant and to discharge the coolant again after it has flowed through the heat sinks. In this way, a cooling system is created that allows access to the units to be cooled when needed.

The electrical power converter can comprise a cooling apparatus comprising a cooling unit as described above and a heat sink detachably connected to the cooling unit as described above.

The electrical power converter can also have:
a circuit board,
further electronic components,
wherein the further electronic components and the unit to be cooled are arranged on or against a circuit board and are connected to electrical contacts.

A preferred outcome of the development is to realize the connection between the unit to be cooled and the heat sink with as little additional material and to be as thin as possible. In view of the considerations, simulations and experiments for this development, the foregoing is particularly achieved when the heat sink through which fluid flows is fixedly connected, in particular in an integrally bonded manner, to the unit to be cooled. This can be done, for example, by a soldered connection, sintering, pressing or direct copper bonding (DCB). The term ‘fixedly’ here can mean: ‘only destructively detachable’. This means using means of connection that cannot be detached even with tools without destroying either the unit to be cooled or the heat sink or both components.

Advantages of the present disclosure are achieved by a method for assembling an electrical power converter for an industrial process assembly, preferably a plasma process assembly or a heating assembly, in particular as described above or below, starting from a heat sink for dissipating heat from a unit to be cooled, in particular an electrical unit, preferably a semiconductor assembly, and a cooling unit. The heat sink has a cooling channel, a coolant inlet fluidically connected to the cooling channel and a coolant outlet fluidically connected to the cooling channel. The cooling unit comprises a first fluid port and a second fluid port. The method comprises a step of detachably fastening the heat sink to the cooling unit, wherein, when the heat sink is fastened to the cooling unit, a first fluidic connection is formed between the coolant inlet of the heat sink and the first fluid port of the cooling unit, and a second fluidic connection is formed between the coolant outlet of the heat sink and the second fluid port of the cooling unit. When the heat sink is fastened to the cooling unit, the first fluidic connection and the second fluidic connection are simultaneously fluid-tightly sealed.

The electrical power converter can be used in particular for power conversion for special power-intensive and instability-prone industrial processes, such as plasma excitation, plasma coating processes, gas laser excitation, particle accelerators, charging and discharging systems for large batteries, such as flow batteries, melting of solids, heating and/or gasification of liquids by, for example, microwave energy or induction heating. All these processes have in common that they are designed to generate and accelerate charged atomic particles in a gas and/or plasma environment or liquid. The electrical power converter can be designed in particular for high power consumption in the range of 1 kW or more, in particular 10 kW or more, preferably 100 kW or more. For loads of this type, there are very high requirements for the stability of the power supply because the processes are highly complex, such as semiconductor manufacturing using plasma processes and/or heating by electromagnetic fields. Typically, power is converted from a mains frequency, which is in the range of approximately 50 Hz to 60 Hz, to different frequencies, which can range from 1 kHz to 200 MHz. Conversion to direct current power, also referred to as DC power, is also conceivable. Converting electrical power to other frequencies requires a plurality of electronic components and modules, in particular power semiconductor components such as transistors or diodes designed for currents ≥10 A and voltages ≥400 V. These electronic components and modules generate a lot of waste heat during operation. Efficiently discharging this always presents a major challenge, which is very advantageously solved with the described devices and methods.

The electrical power converter is preferably designed to stimulate a plasma process, in particular a plasma process for semiconductor manufacturing.

In an aspect, such an electrical power converter will improve the properties of a power supply system that has LDMOS transistors as the elements to be cooled, as disclosed, for example, in DE 10 2013 226 537A1, EP 3 317 964 B1, EP3 317 965 B1. The load capacity of LDMOS transistors in such power supply systems often reaches its limits because they get too hot, even though neither their maximum voltage rating nor their maximum current rating is reached. This means that with an improvement in cooling as described above and below, such power supply systems can be operated much more reliably.

In an aspect, such an electrical power converter will improve the properties of a power supply system that provides very high voltages at its output, in particular voltages greater than or equal to 1 kV, particularly preferably greater than or equal to 2 kV, and in particular greater than or equal to 4 kV. Particularly preferred is when they are also provided in a pulsed manner, as described for example in EP 4 235 737 A1 as a high-power generator. Since the switching elements described there must switch on even when a voltage is applied to their power terminals, these switching operations are particularly high in losses. EP 4 235 737 A1 describes a very complex cooling process, which can be improved with the device and/or method described here.

The patent publications DE 10 2013 226 537A1, EP 3 317 964 B1, EP3 317 965 B1 and EP 4 235 737 A1 are incorporated by reference herein in their entirety.

In an aspect, the coolant inlet and coolant outlet of the heat sink are arranged on the side of the heat sink facing away from the unit to be cooled. This makes it possible, for example, to fluidically contact the heat sink on the side of the heat sink facing away from the unit to be cooled.

In an aspect, the heat sink can be detachably fastened to the cooling unit by means of at least one fastening means, preferably at least one screw. The at least one fastening means can preferably be designed to form the fluidic connections between the heat sink and the cooling unit in such a way that a fluid-tight seal is achieved.

It is advantageous if the fluid-tight sealing of the first fluidic connection and the second fluidic connection can be produced by at least one fastening means that is accessible from the side of the first cooling wall. The fact that the at least one fastening means is accessible from the side of the first cooling wall, for example, makes handling the heat sink easier when inserting and removing it from the cooling unit.

In an aspect, the heat sink can be pressed against the cooling unit by means of at least one fastening means in such a way that liquid-tight fluidic connections can be formed between the first fluid port of the cooling unit and the coolant inlet of the heat sink and between the second fluid port of the cooling unit and the coolant outlet of the heat sink. For example, at least one fastening means can be designed in such a way that, when the heat sink is fastened to the cooling unit, a pressing force can be generated which presses the first and second fluid ports of the cooling unit against the coolant inlet and outlet of the heat sink.

It is advantageous if the cooling apparatus comprises a first sealing element designed to make the first fluidic connection liquid-tight when the heat sink is fastened to the cooling unit. By means of the first sealing element, a fluid-tight first fluidic connection can be formed, for example, when the heat sink is fastened to the cooling unit. For example, when the heat sink is pressed against the cooling unit, the sealing element can be deformed in such a way that the connection between the first cooling port and the coolant inlet is sealed. Preferably, the first sealing element is a first sealing ring that surrounds the first fluid port.

In an aspect, the cooling apparatus comprises a second sealing element designed to make the second fluidic connection liquid-tight when the heat sink is fastened to the cooling unit. By means of the second sealing element, a fluid-tight second fluidic connection can be formed, for example, when the heat sink is fastened to the cooling unit. Preferably, the second sealing element is a second sealing ring that surrounds the second fluid port.

In an aspect, the heat sink is designed in such a way that, when the heat sink is fastened to the cooling unit, a cooling flow can be formed from the first fluid port to the coolant inlet via the cooling channel and the coolant outlet to the second fluid port. In this way, the heat sink can, for example, be supplied with coolant from the cooling unit.

In an aspect, the heat sink consists of or comprises metal, preferably copper. The high thermal conductivity of copper enables effective heat dissipation from the unit to be cooled.

The element to be cooled, in particular the semiconductor assembly, can have a power semiconductor component, the power converter being designed such that the power semiconductor component can be operated in switching or amplifier mode at a frequency greater than 20 kHz and can generate an electrical power loss of ≥500 W.

In an aspect, the heat sink has a cooling channel through which coolant, in particular cooling liquid, preferably cooling water, can flow in an intended flow direction. The cooling channel can preferably have a first cooling wall on the side of the cooling channel facing the unit to be cooled. A plurality of cooling pins can preferably be arranged in the cooling channel or in a portion of the cooling channel, which extend in particular from the first cooling wall into the cooling channel. The plurality of cooling pins can further preferably comprise at least one cooling pin of a first category, which is oriented in a first inclination direction that is inclined obliquely relative to a perpendicular to the first cooling wall. The cooling pins of the plurality of cooling pins can be further preferably arranged such that a cooling pin of the plurality of cooling pins does not intersect another cooling pin of the plurality of cooling pins.

Such a device is described, for example, in the German patent application with the official file number 10 2023 123 660.1, filed on Jan. 9, 2023 with the title: “Heat sink with pressure loss-optimized arrangement of cooling pins within the cooling channel”, which is incorporated in its entirety by reference herein.

In an aspect, in the case of the heat sink, a plurality of cooling pins can be arranged in the cooling channel or in a portion of the cooling channel and extend from the first cooling wall into the cooling channel. A cooling pin is a cooling element which has a length that is greater than the average width or diameter of the cooling element. In particular, a cooling pin can, for example, be designed with a cylindrical or a tapered geometry. The directional extension of the cooling pin can preferably be represented by means of a center line of the cooling pin. According to an exemplary embodiment, for determining such a center line, for example, a line could be laid through the centers of the cross-sections along the cooling pin. The center line of a cooling pin can, for example, be straight, but it can also be slightly curved or slightly bent.

In an aspect, cooling pins of the first category can be oriented in manner inclined obliquely with respect to a perpendicular to the first cooling wall. The term ‘inclined obliquely’ here means that the cooling pins of the first category are neither parallel nor perpendicular to the first cooling wall. It was found that the oblique arrangement of the cooling pins allows for particularly good coolant flow around and improved thermal contact between the cooling pin and the coolant.

In an aspect, the cooling pins of the plurality of cooling pins can be arranged in such a way that no cooling pin intersects any other cooling pin of the plurality of cooling pins. This non-overlapping arrangement of the cooling pins in the cooling channel or in a portion of the cooling channel results in improved flow through the cooling channel and a reduction in pressure loss. The pressure required to convey the coolant through the cooling channel turned out to be particularly low during development.

In an aspect, each cooling pin of the plurality of cooling pins is arranged in such a way that coolant can flow completely around it. This enables high heat transfer from the cooling pins to the coolant.

It is advantageous if the cooling pins of the plurality of cooling pins are arranged in such a way that a cooling pin of the plurality of cooling pins does not touch another cooling pin of the plurality of cooling pins. This creates a spacing between the cooling pins. This facilitates the flow through the cooling channel; and the pressure loss is reduced.

In an aspect, the cooling pins are rod-like. More preferably, the cooling pins preferably have a substantially cylindrical shape. The rod-like or cylindrical design of the cooling pins creates a large contact surface for heat transfer from the cooling pins to the coolant.

In an aspect, the cooling pins have a round or oval cross-section. This can further reduce flow resistance.

It is advantageous if the cooling channel has a second cooling wall on the side of the cooling channel opposite the first cooling wall.

In an aspect, the cooling pins of the plurality of cooling pins extend continuously from the first cooling wall to the second cooling wall. In this way, heat can be supplied to the cooling pins from both the first cooling wall and the second cooling wall. This results in improved heat dissipation.

In an aspect, the first cooling wall is arranged substantially parallel to the second cooling wall. The parallel orientation of the first cooling wall and the second cooling wall ensures a homogeneous flow through the cooling channel with turbulent flow conditions inside.

It is advantageous if the cooling channel has a substantially constant cross-section across the entire heat sink. This results in a constant flow rate of the coolant across the cooling channel. This is advantageous with a local dependence of the flow rate, leading to a desired turbulent system.

In an aspect, the cooling channel has a substantially rectangular cross-section. Furthermore, it is advantageous if the cooling channel is designed as a substantially cuboid cooling channel. Such geometries simplify the formation of flat contact areas for thermal contacting of the units to be cooled.

It is advantageous if the heat sink is a micro heat sink and the unit to be cooled is an electronic component. According to this embodiment, a separate micro heat sink can be provided for each electronic component. This enables heat dissipation that is individually adapted to the electronic component. Preferably, the unit to be cooled is an electronics module.

In an aspect, the heat sink has an inlet, and coolant can be supplied via the inlet at a first end of the cooling channel. More preferably, the heat sink has an outlet, and coolant can be discharged via the outlet at a second end of the cooling channel, the second end of the cooling channel being arranged opposite the first end of the cooling channel. This ensures that the coolant flows through the entire heat sink.

In an aspect, the heat sink is made of metal. Metals generally have high thermal conductivity. According to a preferred embodiment, the heat sink consists of or comprises copper. Copper is a metal with very high thermal conductivity and is therefore preferred for the construction of heat sinks. According to an alternative preferred embodiment, the heat sink consists of or comprises one of molybdenum, stainless steel and nickel.

In an aspect, the cooling pins of the heat sink are produced by means of an additive manufacturing process, in particular selective laser melting (SLM). Using such additive manufacturing processes, the cooling pins can be applied to the first cooling wall of the heat sink in virtually any orientation. Even in additive manufacturing, certain restrictions must be observed regarding the structure, e.g., internally, such as the build angle, which in particular should be less than 45°, otherwise it would not be possible without a support structure.

In an aspect, the unit to be cooled is mechanically and thermally connected to the heat sink.

In an aspect, the unit to be cooled is connected to the heat sink by at least one of the following: by at least one soldered connection, by at least one welded connection, by sintering. For example, if the heat sink is soldered fixedly to the unit to be cooled, the soldering enables improved thermal coupling. Improved thermal coupling between the heat sink and the unit to be cooled can also be achieved, for example, by means of a welded connection or by sintering.

In an aspect, the unit to be cooled is connected to the heat sink by means of a layer of thermal paste. In this case also, it can be advantageous to be able to remove the heat sink from the cooling unit if necessary.

In an aspect, the electronics module described above has a circuit board to which the unit to be cooled has a fixed mechanical connection. This fixed mechanical connection can be achieved, for example, by soldering electrical connections of the unit to be cooled to the circuit board. In this embodiment, the circuit board, the unit to be cooled and the heat sink form a structural unit which, for example, can be used in its entirety in the cooling unit.

In an aspect, the electronics module comprises a plurality of units to be cooled which have a fixed mechanical connection to the circuit board as well as a plurality of heat sinks. The electronics module with its plurality of heat sinks can be inserted in its entirety into the cooling unit. The cooling unit preferably has a plurality of receptacles designed to accommodate the plurality of heat sinks. The fact that the electronics module can be removed from the cooling unit makes maintenance easier, for example.

In an aspect, the cooling unit has at least one receiving device for at least one fastening means.

In an aspect, the heat sink can be fastened by means of at least one fastening means which is accessible from the side of the first cooling wall and which engages in the at least one receiving device. If the at least one fastening means engages in the at least one receiving device on the sides of the cooling unit, the heat sink can, for example, be fastened to the cooling unit.

In an aspect, the fluid-tight sealing of the first fluidic connection and the second fluidic connection can be produced by at least one fastening means that is accessible from the side of the unit to be cooled. If at least one fastening means is accessible from the side of the unit to be cooled, insertion and removal of the heat sink from the cooling unit can be facilitated.

It is advantageous if the cooling unit has a receptacle for the heat sink into which the heat sink can be inserted. This allows, for example, the heat sink to be fixed precisely in the cooling unit.

In an aspect, the cooling unit is designed to supply coolant to a plurality of heat sinks and to discharge coolant from the plurality of heat sinks.

In an aspect, the cooling unit has a plurality of receptacles into which a plurality of heat sinks can be inserted. This makes it possible, for example, to insert an electronics module, which has a plurality of heat sinks, in its entirety into the receptacles of the cooling unit.

In an aspect, the cooling unit consists entirely of or partially comprises metal, or consists entirely of or partially comprises plastic.

In an aspect, grooves are provided within the cooling unit into which pipes can be pressed. The pipes can, for example, comprise a first flow channel for supplying coolant and a second flow channel for discharging coolant.

In an aspect, the wall of the pipes consists entirely or predominantly of a material, preferably copper, which has a higher thermal conductivity compared to other regions of the cooling unit, or comprises copper. The high thermal conductivity of the pipe walls can, for example, further improve the heat dissipation from the unit to be cooled.

In an aspect, the cooling unit comprises a distribution unit that has the first fluid port and the second fluid port. The distribution unit is preferably designed to supply at least one heat sink with coolant and to discharge the returning coolant.

It is advantageous if the distribution unit is designed as a cooling insert which, compared to other regions of the cooling unit, consists of or comprises a material with higher thermal conductivity, preferably copper. For example, the cooling insert can be in thermal contact with the heat sink, so that the heat dissipation of the heat sink is improved by the thermal contact with the cooling insert. This saves costs and weight, since the entire carrier unit does not have to be made from the more expensive and usually heavier material, such as copper.

In an aspect, the cooling unit comprises a carrier unit. The distribution unit can be inserted into the carrier unit.

In an aspect, the carrier unit consists entirely of or partially comprises metal, preferably aluminum.

In an aspect, within the cooling apparatus, a cooling flow can be formed from the first fluid port to the coolant inlet via the cooling channel and the coolant outlet to the second fluid port. This cooling flow can be used, for example, to remove the heat generated by the unit to be cooled.

In an aspect, the cooling unit is designed to supply coolant, in particular cooling liquid, preferably cooling water, to the heat sink via the first fluid port and to discharge it from the heat sink via the second fluid port.

Further advantageous embodiments are described in more detail below with reference to several exemplary embodiments shown in the drawings, to which the development is not limited, however.

In the following description of preferred embodiments of the present development, the same reference signs denote the same or comparable components.

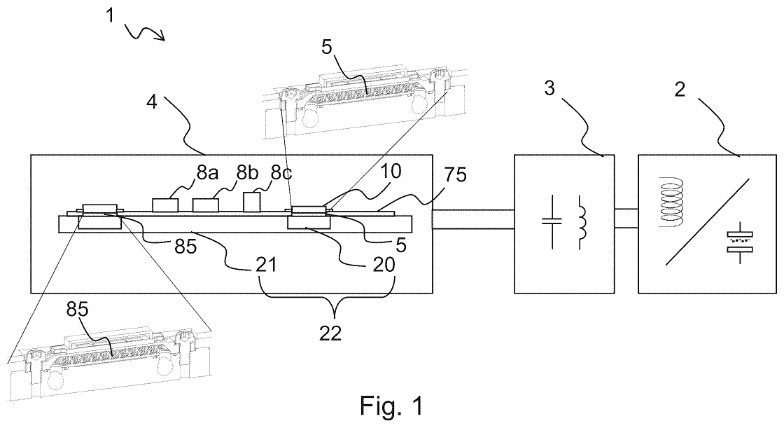

FIG. 1 shows an industrial process assembly 1, preferably a plasma process assembly or a heating assembly.

The industrial process assembly 1 has:
an electrical power converter 4,
a load 2, preferably a plasma process or heating process, e.g., an induction or microwave heating process, wherein the load 2 is electrically connected to the electrical power converter 4, so that the electrical power converter 4 can supply the load 2 with the required electrical power,
optionally an additional adaptation unit 3, which is connected between the power converter 4 and the load 2.
   The power converter 4 has:
a heat sink 5, and a further heat sink 85, as described above and below,
a cooling unit 22, which, as described above and below, has one or more distribution units 20 and a carrier unit 21,
a circuit board 75,
a unit 10 to be cooled, in particular an electrical unit, preferably a semiconductor assembly, preferably having a power semiconductor component,
further electronic components 8a, 8b, 8c,
wherein the further electronic components 8a, 8b, 8c and the unit 10 to be cooled are arranged on or against a circuit board 75 and are connected to electrical contacts,
wherein the unit 10 to be cooled has a fixed, in particular integrally bonded, connection to the heat sink 5, 85.

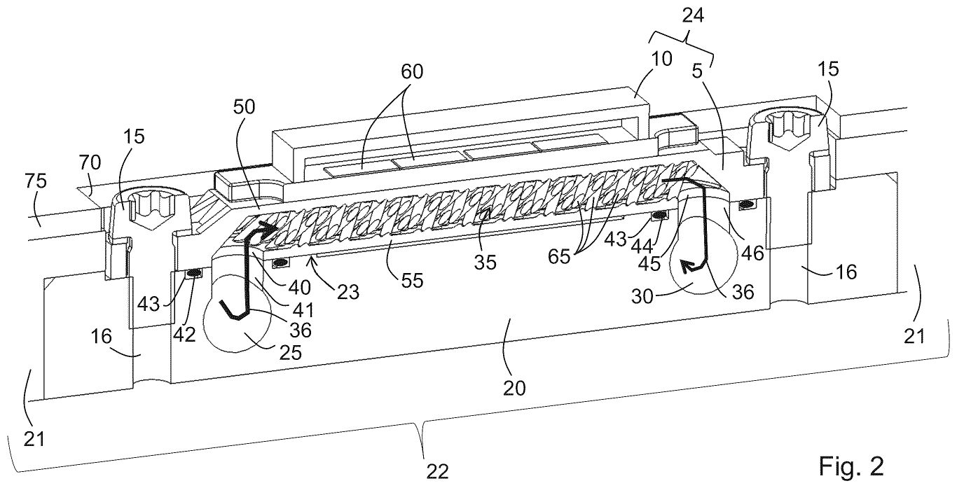

FIG. 2 shows that a plurality of cooling pins 65 can be arranged in the cooling channel 35 or in a portion of the cooling channel 35, which extend from the first cooling wall 50 into the cooling channel 35.

FIG. 2 further shows that the plurality of cooling pins 65 can comprise at least one cooling pin of a first category which is oriented in a first inclination direction which is inclined obliquely relative to a perpendicular to the first cooling wall 50.

FIG. 2 further shows that the cooling pins of the plurality of cooling pins 65 can be arranged such that a cooling pin of the plurality of cooling pins 65 does not intersect another cooling pin of the plurality of cooling pins 65.

It can further be seen from FIG. 2 that the plurality of cooling pins 65 can comprise at least one cooling pin of a second category which is oriented in a second inclination direction which is inclined obliquely relative to the perpendicular to the first cooling wall, the second inclination direction being different from the first inclination direction. In this embodiment, the plurality of pins comprises 65 cooling pins of the first category, which are oriented in a first inclination direction, and cooling pins of the second category, which are oriented in a second inclination direction. The different orientations of the cooling pins create a flow pattern in the cooling channel 35 that has proven advantageous for efficient heat dissipation.

FIG. 2 further shows that the plurality of cooling pins 65 can be arranged such that a cooling pin of the first category overlaps with a cooling pin of the second category at a viewing angle parallel to the cooling wall, in particular at a viewing angle of the coolant flow direction. ‘Overlapping’ here means that at least one cooling pin of the first category at least partially covers another cooling pin of the second category in the given viewing direction. Such an assembly can improve the turbulence of the coolant at the cooling pins and consequently the heat transfer from the cooling pins to the coolant.

FIG. 2 further shows that the plurality of cooling pins 65 can be arranged such that a cooling pin of the first category is interwoven with two cooling pins of the second category at a viewing angle parallel to the cooling wall, in particular at a viewing angle of the coolant flow direction. The term ‘interwoven’ here means that at least one first cooling pin of the first category at least partially covers a second cooling pin of the second category in the given viewing direction, and that the first cooling pin itself is also at least partially covered by a further cooling pin of the second category in the given viewing direction. Such an assembly can further improve the turbulence of the coolant at the cooling pins and consequently the heat transfer from the cooling pins to the coolant.

FIG. 2 shows a cooling apparatus in longitudinal section. The cooling apparatus comprises a heat sink 5, 85, which is designed to cool a unit 10 to be cooled that is attached to the heat sink 5, 85. The unit 10 to be cooled can in particular be an electrical unit, preferably a semiconductor assembly.

The heat sink 5, 85 is detachably connected to a cooling unit 22. In the example shown in the figures, the cooling unit 22 comprises a distribution unit 20 designed to supply the heat sink 5, 85 with coolant. Furthermore, the cooling unit 22 comprises a carrier unit 21 into which the distribution unit 20 is inserted. The cooling unit 22 has a receptacle 23 into which the heat sink 5, 85 can be detachably inserted. The heat sink 5, 85 is then fastened to the cooling unit 22 by means of at least one fastening means 15, preferably by means of one or more screws. The cooling unit 22 has at least one receiving device 16 for the at least one fastening means 15. To separate the heat sink 5 again from the cooling unit 22, the at least one fastening means 15 is first detached. The heat sink 5, together with the unit 10 to be cooled which is fastened to it, can then be removed from the receptacle 23 of the cooling unit 22.

Preferably, the unit 10 to be cooled is mechanically and thermally connected to the heat sink 5, 85. The unit 10 to be cooled can be connected to the heat sink 5, 85, for example, by means of one or more soldered connections. The unit 10 to be cooled can be connected to the heat sink 5, 85, for example by means of sintering. Alternatively, the unit 10 to be cooled can be welded to the heat sink 5, 85. As another, albeit less advantageous, alternative, the unit 10 to be cooled could also be connected to the heat sink 5, 85 by means of a layer of thermal paste. The result of the development, however, is to realize the connection between the unit 10 to be cooled and the heat sink 5, 85 with as little additional material and to be as thin as possible. In view of the considerations, simulations and experiments for this development, the foregoing is particularly achieved when the heat sink through which fluid flows is fixedly connected, in particular in an integrally bonded manner, to the unit 10 to be cooled. This can be done, for example, by a soldered connection, sintering, pressing or direct copper bonding (DCB). The term ‘fixedly’ here can mean: ‘only destructively detachable’. This means using means of connection that cannot be detached even with tools without destroying either the unit 10 to be cooled or the heat sink 5, 85 or both components. It was further realized that such a solution will only be feasible if a new solution can be found for the interchangeability of the circuit board component with electronic components and, in particular, with the cooling unit 10 to be cooled fastened to it. This was achieved with the disclosed heat sink 5.

The heat sink 5, 85 and the unit 10 to be cooled, which is mechanically, fixedly connected to the heat sink 5, 85, together form an electronics module 24. This electronics module 24 can be inserted into the receptacle 23 of the cooling unit 22 and removed again from this receptacle 23.

The cooling unit 22 is designed to supply coolant to the heat sink 5, 85 attached to the cooling unit 22 and to discharge the coolant again after the coolant has flowed through the heat sink 5, 85. Within the cooling unit 22, a first flow channel 25 can be seen, via which coolant can be supplied to the heat sink 5, 85. Within the cooling unit 22, a second flow channel 30 can be seen, via which the coolant can be discharged. The heat sink 5, 85 has a cooling channel 35 through which the coolant can flow. A coolant inlet 40 is provided at a first end of the cooling channel 35 and a coolant outlet 45 is provided at the second end of the cooling channel 35 opposite the first end. The coolant inlet 40 and the coolant outlet 45 are fluidically connected to the cooling channel 35.

The cooling unit 22 comprises a first fluid port 41, which is fluidically connected to the first flow channel 25, and a second fluid port 46, which is fluidically connected to the second flow channel 30. When the heat sink 5 is inserted and subsequently fastened in the receptacle 23, a first fluidic connection is formed between the first fluid port 41 and the coolant inlet 40, and a second fluidic connection is formed between the second fluid port 46 and the coolant outlet 45.

To seal the first fluidic connection, a first sealing ring 42 is arranged in a groove 43 between the cooling unit 22 and the heat sink 5, the sealing ring 42 completely surrounding the first fluid port 41. Likewise, a second sealing ring 44, completely surrounding the second fluid port 46, is provided at the second fluid port 46 and is arranged in a groove 43 between the cooling unit 22 and the heat sink 5. When the at least one fastening means 15 is fastened, for example the at least one screw is tightened, the heat sink 5 is pressed against the first fluid port 41 and the first sealing ring 42 as well as against the second fluid port 46 and the second sealing ring 44. As a result of this pressing, a liquid-tight first fluidic connection and a liquid-tight second fluidic connection are formed between the cooling unit 22 and the heat sink 5.

As shown in FIG. 2, a cooling flow 36 can be formed within the cooling apparatus. The coolant flows from the first flow channel 25 via the first fluid port 41 and the coolant inlet 40 into the cooling channel 35. The coolant flows through the cooling channel 35 and is discharged again via the coolant outlet 45, the second fluid port 46 and the second flow channel 30.

The heat sink 5 has a first cooling wall 50 on the side facing the unit 10 to be cooled. On the side of the heat sink 5 facing away from the unit 10 to be cooled, the cooling channel 35 is delimited by a second cooling wall 55, which is opposite the first cooling wall 50. Preferably, the second cooling wall 55 is designed parallel to the first cooling wall 50.

In the example shown in FIG. 2, the unit 10 to be cooled comprises an assembly of transistors 60. The heat generated during the operation of the transistors 60 is dissipated via the coolant flowing in the cooling channel 35.

To improve the thermal exchange between the coolant flowing through the cooling channel 35 and the heat sink 5, a plurality of cooling pins 65 can be arranged inside the cooling channel 35, which extend into the cooling channel 35 from the first cooling wall 50 and/or from the second cooling wall 55. Coolant flows around the cooling pins 65 and the cooling pins ensure improved thermal coupling between the heat sink 5 and the coolant.

In FIG. 2, it can also be seen that the unit 10 to be cooled, together with the heat sink 5 arranged below it, is arranged within a first recess 70 of a circuit board 75.

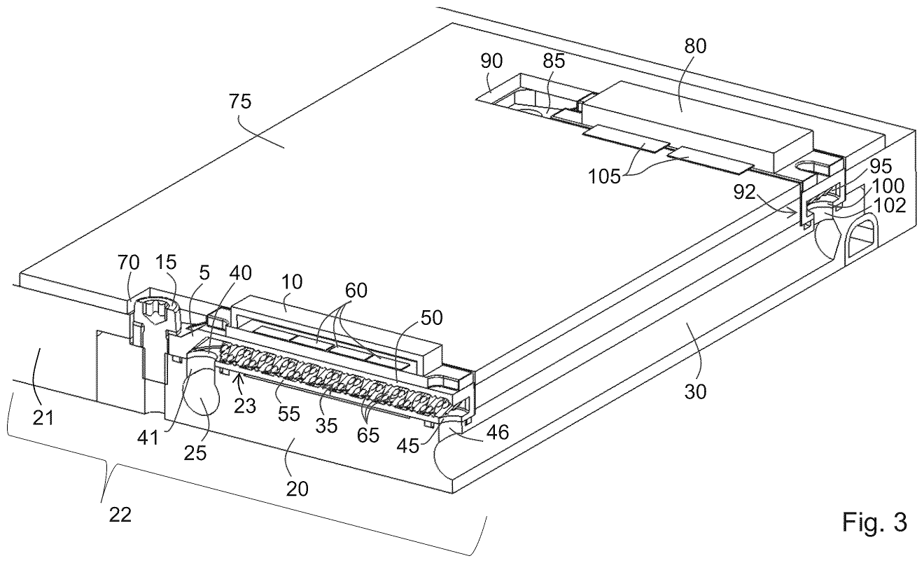

In FIG. 3, the arrangement of the unit 10 to be cooled within the first recess 70 of the circuit board 75 can be clearly seen. FIG. 3 shows the circuit board 75, which is arranged on the cooling unit 22. Within the first recess 70 of the circuit board 75, the unit 10 to be cooled is shown in longitudinal section together with the associated heat sink 5. The heat sink 5 is inserted into the receptacle 23 of the cooling unit 22.

In addition to the unit 10 to be cooled, a further unit 80 to be cooled can be seen in FIG. 3 together with a further heat sink 85 arranged below it. The further unit 80 to be cooled is arranged within a further recess 90 provided in the circuit board 75 and the associated further heat sink 85 is inserted into a further receptacle 92 of the cooling unit 22. The further heat sink 85 has a further cooling channel 95 through which coolant flows. Furthermore, electrical connection terminals 105 can be seen on the further unit 80 to be cooled, which are provided for the formation of electrical connections between the further unit 80 to be cooled and the circuit board 75. The unit 10 to be cooled also has electrical connection terminals for connection to the circuit board 75.

The cooling unit 22 shown in FIG. 3 is designed to supply coolant to a plurality of heat sinks and to discharge the coolant after it has flowed through the heat sinks. In the example of FIG. 3, the cooling unit 22 is designed to supply coolant both to the heat sink 5 and to the further heat sink 85 and then to discharge it again from both the heat sink 5 and the further heat sink 85. The cooling unit 22 is designed in particular to distribute the coolant evenly among the various heat sinks.

The further heat sink 85 is also fluidically connected to the cooling unit 22 when it is fastened in the further receptacle 92. In the sectional view of FIG. 3, it can be seen that the further cooling channel 95 is connected via the further coolant outlet 100 and the further second fluid port 102 to the second flow channel 30, via which the coolant is discharged.

The circuit board 75 shown in FIG. 3, together with the units 10 and 80 to be cooled that are fastened to the circuit board 75 and the heat sinks 5 and 85, forms a structural unit which, in its entirety, can be placed on and removed again from the cooling unit 22, and which is therefore detachably connectable to the cooling unit 22. When placing this structural unit on the cooling unit 22, the heat sinks 5, 85 attached to the units 10, 80 to be cooled are inserted into the associated receptacles 23, 92 of the cooling unit 22. Subsequently, the heat sinks 5, 85 are fastened to the cooling unit 22 by means of at least one fastening means 15, and fluidic connections for supplying and discharging coolant between the heat sinks 5, 85 and the cooling unit 22 are formed when the heat sinks 5, 85 are fastened to the cooling unit 22. The cooling unit 22 is designed to supply all the heat sinks 5, 85 of the structural unit evenly with coolant and to discharge the coolant again after it has flowed through the heat sinks 5, 85.

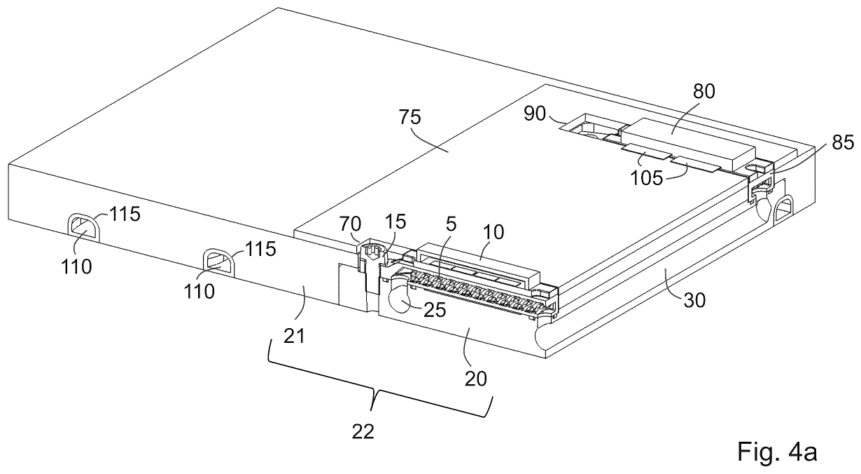

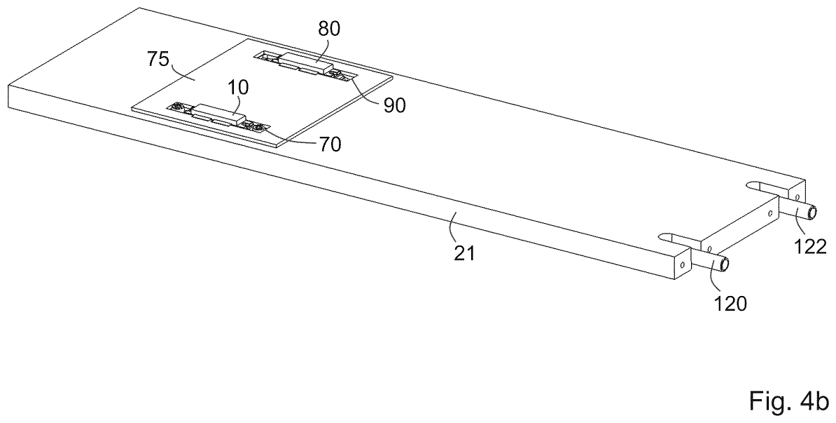

FIG. 4a shows a further view of the circuit board 75 obliquely from above, in which, in FIG. 4a, part of the carrier unit 21 can be seen. Furthermore, in the sectional view of FIG. 4a, pipes 110 can be seen which are fitted into grooves 115 provided for this purpose on the underside of the carrier unit 21.

The heat sinks 5, 85 are preferably made of metal, more preferably of copper. Alternatively, the heat sinks 5, 85 could, for example, be made of stainless steel, nickel or molybdenum. The carrier unit 21 can, for example, consist entirely of or partially comprise metal, but the carrier unit can also consist entirely of or partially comprise plastic. Preferably the carrier unit 21 consists entirely of or partially comprises aluminum. The walls of the pipes 110 preferably consist of or comprise copper.

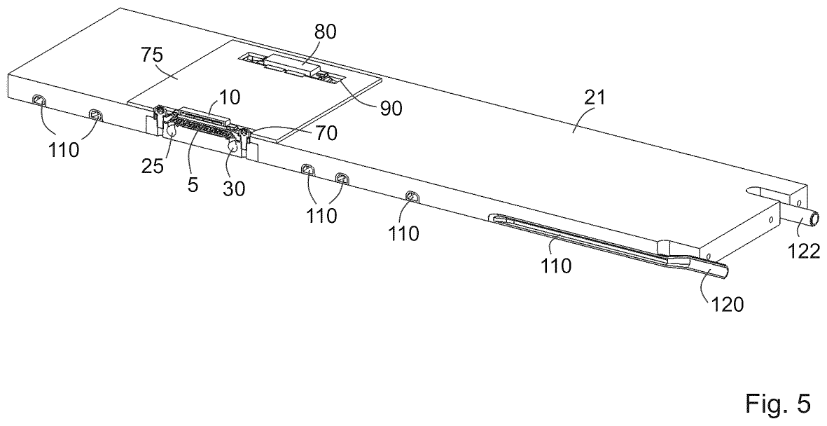

FIGS. 4b and 5 show the carrier unit 21 in its entirety, in which the circuit board 75 with the units 10 and 80 to be cooled can be seen. The carrier unit 21 is provided with a first coolant connection 120 for supplying coolant and a second coolant connection 122 for discharging coolant. In the longitudinal section through the unit 10 to be cooled, shown in FIG. 5, the heat sink 5, the first flow channel 25 and the second flow channel 30 can also be seen. Furthermore, some of the pipes 110 arranged on the underside of the carrier unit 21 can be seen in the sectional view of FIG. 5.

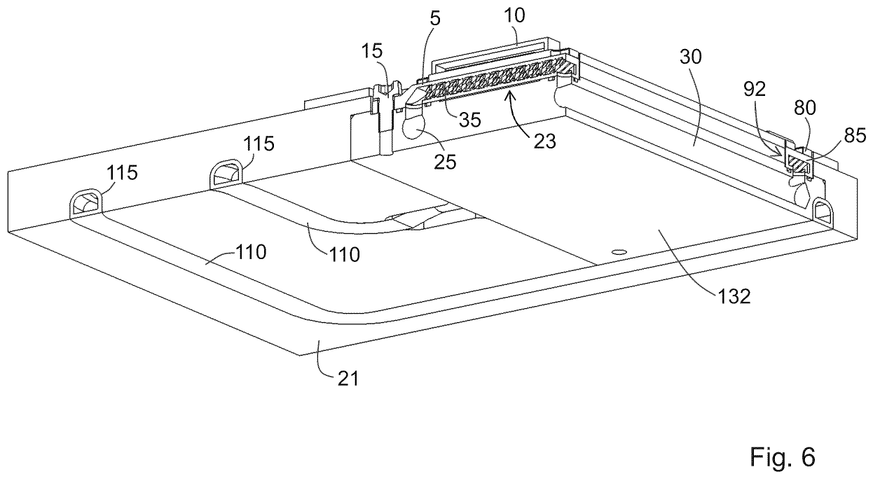

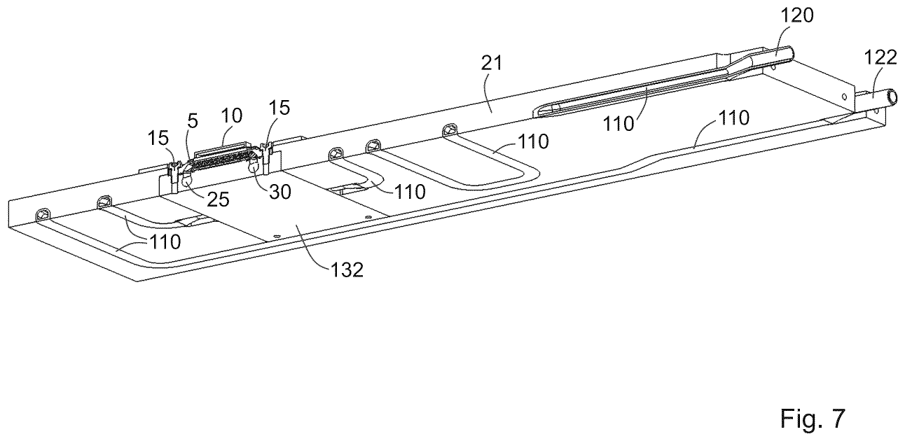

FIGS. 6 and 7 show two views of the carrier unit 21 obliquely from below. FIG. 6 shows the units 10 and 80 to be cooled as well as the heat sinks 5 and 85. FIGS. 6 and 7 show that the distribution unit is designed in the form of a cooling insert 132, wherein the cooling insert 132 preferably consists of or comprises a metal with high thermal conductivity, preferably copper. The cooling insert 132 is inserted into the carrier unit 21.

The receptacle 23 for the heat sink 5 and the further receptacle 92 for the further heat sink 85 are designed as part of the cooling insert 132. The heat sink 5 is fastened to the cooling insert 132 by means of at least one fastening means 15. Preferably, the heat sink 5 is screwed onto the cooling insert 132. The use of a copper cooling insert 132 in the regions where the heat sinks 5 and 85 are arranged enables improved heat dissipation from the heat sinks 5 and 85.

When using a cooling insert 132 made of copper, the structures provided for fluidic contacting of the heat sinks 5 and 85 are arranged within the cooling insert 132. In this respect, the first flow channel 25, the first fluid port 41, the second flow channel 30, the second fluid port 46 and the further second fluid port 102 are formed within the cooling insert 132. Furthermore, in FIG. 6 and FIG. 7, the pipes 110 can be seen, which are pressed into the grooves 115 provided for this purpose on the underside of the carrier unit 21. Preferably, the wall of the pipes 110 consists of or comprises a metal with a high thermal conductivity, preferably copper. More preferably, the pipes 110 are connected to the cooling insert 132 and are designed to supply cold coolant to the cooling insert 132 and to discharge the heated coolant.

FIG. 7 shows the entire carrier unit 21 from the underside. In FIG. 7, in addition to the cooling insert 132 and the pipes 110 pressed into the grooves 115, the coolant connections 120 and 122 for supplying and discharging coolant can also be seen.

The features disclosed in the above description and the drawings can be important both individually and in any combination for the realization of the development in its various embodiments.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. An electrical power converter for an industrial process assembly, comprising:
a heat sink;
an electrical unit to be cooled;
a circuit board; and
further electronic components, wherein the further electronic components and the electrical unit to be cooled are arranged on or against the circuit board and are connected to electrical contacts,
wherein the unit to be cooled has an integrally bonded connection to the heat sink,
wherein the heat sink is configured to dissipate heat from the electrical unit to be cooled,
wherein the heat sink includes:
a cooling channel, and
a coolant inlet and a coolant outlet, which are both fluidically connected to the cooling channel, the coolant inlet and the coolant outlet being configured to supply and discharge cooling liquid, and
wherein:
the heat sink is constructed in monolithic form from one material,
the heat sink is mechanically and thermally connected to the electrical unit to be cooled,
the heat sink is detachably fastened to a cooling unit comprising a first fluid port,
a first fluidic connection is configured to be formed between the coolant inlet of the heat sink and the first fluid port of the cooling unit when the heat sink is fastened to the cooling unit, and
the heat sink is configured to be fastened to the cooling unit simultaneously with the first fluidic connection being fluid-tightly sealed.

2. The electrical power converter according to claim 1, wherein the heat sink is configured to be detachably fastened to the cooling unit by at least one fastener.

3. The electrical power converter according to claim 1, wherein the fluid-tight sealing of the first fluidic connection is configured to be produced by at least one fastener accessible from a side of the first cooling wall.

4. The electrical power converter according to claim 1, wherein the heat sink is configured such that, when the heat sink is fastened to the cooling unit, a cooling flow is configured to be formed from the first fluid port to the coolant inlet via the cooling channel.

5. The electrical power converter according to claim 1, wherein the electrical power converter is configured to stimulate a semiconductor manufacturing plasma process.

6. The electrical power converter according to claim 1, wherein the heat sink has a cooling channel through which the cooling liquid is configured to flow in an intended flow direction,
wherein the cooling channel has a first cooling wall on a side of the cooling channel facing the electrical unit to be cooled,
wherein a plurality of cooling pins are arranged in the cooling channel or in a portion of the cooling channel, the plurality of cooling pins extending from the first cooling wall into the cooling channel,
wherein the plurality of cooling pins comprises at least one cooling pin of a first category which is oriented in a first inclination direction, the first inclination direction being inclined obliquely relative to a direction perpendicular to the first cooling wall, and
wherein each of the plurality of cooling pins are arranged such that a respective cooling pin of the plurality of cooling pins does not intersect any other cooling pin of the plurality of cooling pins.

7. The electrical power converter according to claim 6, wherein the plurality of cooling pins of the heat sink are additively manufactured by selective laser melting.

8. The electrical power converter according to claim 1, wherein the heat sink is additively manufactured by selective laser melting.

9. The electrical power converter according to claim 1, wherein the electrical unit to be cooled has at least one laterally-diffused metal-oxide semiconductor (LDMOS) transistor.

10. The electrical power converter according to claim 1, wherein the electrical power converter is configured to generate a high voltage greater than or equal to 2 kV.

11. The electrical power converter according to claim 1, wherein the electrical unit to be cooled is connected to the heat sink by at least one of the following: at least one soldered connection, at least one welded connection, and/or sintering.

12. The electrical power converter according to claim 1, wherein the circuit board has a fixed mechanical connection with the electrical unit to be cooled.

13. An electrical power converter for an industrial process assembly, comprising:
a cooling unit configured to supply a heat sink which has a coolant inlet and a coolant outlet with cooling liquid, wherein the cooling unit comprises:
a first flow channel and a second flow channel,
a first fluid port which is fluidically connected to the first flow channel,
a second fluid port which is fluidically connected to the second flow channel,
wherein the cooling unit is configured such that:
the heat sink is configured to be detachably fastened to the cooling unit,
a first fluidic connection is configured to be formed between the coolant inlet of the heat sink and the first fluid port of the cooling unit when the heat sink is fastened to the cooling unit, and a second fluidic connection is configured to be formed between the coolant outlet of the heat sink and the second fluid port of the cooling unit when the heat sink is fastened to the cooling unit,
the heat sink is configured to be fastened to the cooling unit simultaneously with the first fluidic connection and the second fluidic connection being fluid-tightly sealed;
a circuit board; and
further electronic components, wherein the further electronic components and the an electrical unit to be cooled are arranged on or against the circuit board and are connected to electrical contacts.

14. The electrical power converter according to claim 1, further comprising:
a further heat sink; and
a further electrical unit to be cooled,
wherein the further electrical unit to be cooled has a fixed integrally bonded connection to the further heat sink,
wherein the further heat sink is configured to dissipate heat from the further electrical unit to be cooled,
wherein the further heat sink comprises:
a further cooling channel,
a further coolant inlet and a further coolant outlet, which are both fluidically connected to the further cooling channel, configured to supply and discharge the cooling liquid, and
wherein
the further heat sink is constructed in monolithic form from one material, the further heat sink being mechanically and thermally connected to the further electrical unit to be cooled,
the further heat sink is detachably fastened to the cooling unit, which comprises a further fluid port,
a further fluidic connection is formed between the further coolant inlet of the further heat sink and the further fluid port of the cooling unit when the further heat sink is fastened to the cooling unit, and
the further heat sink is configured to be fastened to the cooling unit simultaneously with the further fluidic connection being fluid-tightly sealed.

15. The electrical power converter according to claim 14, wherein the further heat sink is configured to be detachably fastened to the cooling unit by at least one further fastener, and wherein the fluid-tight sealing of the further fluidic connection is configured to be produced by the at least one further fastener.

16. The electrical power converter according to claim 14, wherein the further electrical unit to be cooled is connected to the further heat sink by at least one of a soldered connection, a welded connection, and/or sintering.

17. A method for assembling the electrical power converter according to claim 1, from the method comprising:
detachably fastening the heat sink to the cooling unit, wherein, when the heat sink is fastened to the cooling unit, a first fluidic connection is formed between the coolant inlet of the heat sink and the first fluid port of the cooling unit and a second fluidic connection is formed between the coolant outlet of the heat sink and the second fluid port of the cooling unit, and wherein, when the heat sink is fastened to the cooling unit, the first fluidic connection and the second fluidic connection are simultaneously fluid-tightly sealed.
